(19) United States
(12) Patent Application Publication
(10) Pub. No.: US 2026/0081619 A1
(43) Pub. Date: Mar. 19, 2026

(54) DATA COMPRESSION DEVICE, DATA COMPRESSION/DECOMPRESSION SYSTEM, AND MEMORY SYSTEM

(71) Applicant: Kioxia Corporation, Tokyo (JP)

(72) Inventors: Sho KODAMA, Kamakura Kanagawa (JP); Keiri NAKANISHI, Kawasaki Kanagawa (JP); Daisuke YASHIMA, Tachikawa Tokyo (JP)

(73) Assignee: Kioxia Corporation, Tokyo (JP)

(21) Appl. No.: 19/074,514

(22) Filed: Mar. 10, 2025

(30) Foreign Application Priority Data
Sep. 18, 2024 (JP) 2024-161015

(51) Int. Cl. H03M 7/30

(52) U.S. Cl. CPC H03M 7/3088; H03M 7/6005; H03M 7/6011

(57) ABSTRACT

According to one embodiment, a data compression device includes N data compression circuits each including a dictionary buffer, and a dictionary buffer concatenation control circuit. The dictionary buffer concatenation control circuit controls switching between a first mode in which the N data compression circuits operate independently and a second mode in which the N data compression circuits cooperate. The dictionary buffer concatenation control circuit inputs, in the first mode, mutually different uncompressed data to the N data compression circuits, concatenates, in the second mode, N dictionary buffers by storing oldest dictionary data of an i-th dictionary buffer in an (i+1)-th dictionary buffer, and inputs the same uncompressed data to N data compression circuits.

### CROSS-REFERENCE TO RELATED APPLICATIONS

This application is based upon and claims the benefit of priority from Japanese Patent Application No. 2024-161015, filed Sep. 18, 2024, the entire contents of which are incorporated herein by reference.

### FIELD

Embodiments described herein relate generally to a data compression device, a data compression/decompression system, and a memory system.

### BACKGROUND

For example, in a data compressor with an LZ77-type dictionary compression circuit, data which has been previously input is buffered in a dictionary buffer, and data which matches the input data is retrieved in the previous data in the dictionary buffer. If the matching data is stored in the dictionary buffer, the matching data is replaced with a match distance indicating an address of the dictionary buffer and a match length indicating a length of the matching data, which are output as dictionary compression results, and compression is thereby executed. One of methods of improving the compression efficiency of the dictionary compression circuit is to increase the dictionary size (i.e., a parameter indicating how many bytes can be retrieved for previous matching or not). However, if the dictionary size increases, the circuit size of the dictionary buffer and the dictionary search logic for searching for matches from the dictionary buffer increases.

### BRIEF DESCRIPTION OF THE DRAWINGS

FIG. 1 is a view showing an example of a configuration of a memory system of a first embodiment.

FIG. 2 is a view showing a comparative example to illustrate increasing a circuit scale of a dictionary compressor as a dictionary size is increased to improve a compression efficiency of the dictionary compressor.

FIG. 3 is a view showing an example of a configuration of a data compression device in the memory system of the first embodiment.

FIG. 4 is a view showing both a manner of viewing a compressed IP with and without the dictionary buffer concatenation in the data compression device and a configuration of a dictionary buffer in a case where the dictionary buffer concatenation is formed, in the memory system of the first embodiment.

FIG. 5 is a view showing an example of a configuration of a data compression device in a memory system of a second embodiment.

FIG. 6 is a view showing a configuration of a dictionary buffer in a case where dictionary buffer concatenation of the data compression device is formed, in the memory system of the second embodiment.

FIG. 7 is a view showing an example of a configuration of a data compression device and a data decompression device in a memory system of a third embodiment.

FIG. 8 is a view showing a configuration of a dictionary buffer in a case where dictionary buffer concatenation of the data compression device is formed, in the memory system of the third embodiment.

FIG. 9 is a view showing an example of a configuration of a data compression device and a data decompression device in a memory system of a fourth embodiment.

FIG. 10 is a view showing a configuration of a dictionary buffer in a case where dictionary buffer concatenation of the data compression device is formed, in the memory system of the fourth embodiment.

FIG. 11 is a view showing an example of a configuration of a data compression device in a memory system of a fifth embodiment.

FIG. 12 is a view showing a configuration of a dictionary buffer in a case where dictionary buffer concatenation of the data compression device is formed, in the memory system of the fourth embodiment.

### DETAILED DESCRIPTION

In general, according to one embodiment, a data compression device includes N (N is an integer of two or more) data compression circuits, a dictionary buffer concatenation control circuit, and a longest match selection circuit. The N data compression circuits each includes a first dictionary compression circuit. The dictionary buffer concatenation control circuit controls switching between a first mode and a second mode. The first mode is a mode in which each of the N data compression circuits operate independently. The second mode is a mode in which the N data compression circuits cooperate. In the second mode, the longest match selection circuit selects a dictionary compression result with a longest match length from among the dictionary compression results of the N first dictionary compression circuits in the N data compression circuits. The first dictionary compression circuit includes a dictionary buffer for buffering the uncompressed data to be input and compressed, as dictionary data. In the first mode, the dictionary buffer concatenation control circuit inputs the N uncompressed data different from each other to the N data compression circuits. In the second mode, the dictionary buffer concatenation control circuit concatenates the N dictionary buffers by storing, when registering the dictionary data to an i-th (i is an integer of 1 or more and N−1 or less) dictionary buffer out of the N dictionary buffers of the N data compression circuits, oldest dictionary data stored in the i-th dictionary buffer in the (i+1)-th dictionary buffer, and inputs same uncompressed data to the N data compression circuits.

Embodiments will be described hereinafter with reference to the accompanying drawings.

### First Embodiment

First, a first embodiment will be described.

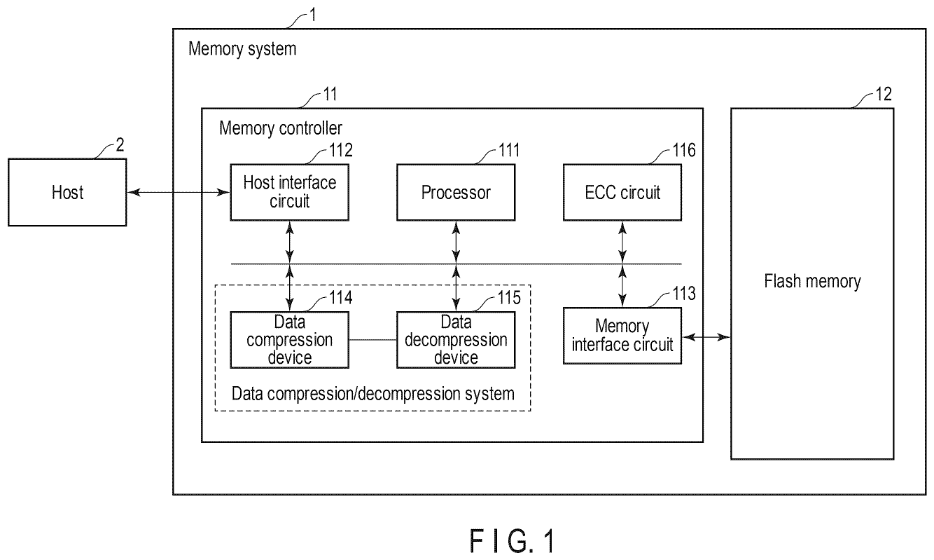

FIG. 1 is a view showing an example of a configuration of a memory system 1 of the first embodiment. FIG. 1 shows an example of a configuration of an information processing system including both a memory system 1 and a host 2 connected to the memory system 1 as a storage. The host 2 is an information processing apparatus such as a server or a personal computer.

The memory system 1 includes a memory controller 11 and a flash memory 12. In this example, the memory system 1 is implemented as a solid state drive (SSD). The memory system 1 can be implemented as not only SSD, but also various types of data storage devices. In other words, the memory system 1 can be equipped with not only the flash memory 12, but also various types of storage media.

The memory controller 11 is a device that controls the overall operations of the memory system 1. The memory controller 11 includes a processor 111, a host interface circuit 112, a memory interface circuit 113, a data compression device 114, a data decompression device 115, and an error check and correct (ECC) circuit 116.

The processor 111 implements various processes that the memory controller 11 is to execute, by running programs referred to as firmware or the like. The various processes that the memory controller 11 is to execute include a write process of writing data to the flash memory 12 in response to write commands from the host 2, a read process of reading data stored in the flash memory 12 in response to read commands from the host 2, and the like. An example in which the various processes to be executed by the memory controller 11 are implemented by the processor 111 executing firmware. However, the processes may also be improved by dedicated hardware built in the memory controller 11, such as an electrical circuit.

The host interface circuit 112 controls communication conforming to predetermined communication standards with the host 2. The memory interface circuit 113 controls writing data to the flash memory 12 and reading data from the flash memory 12.

The data compression device 114 compresses the write data that is requested to be written to the flash memory 12 by the write commands to generate compressed data. The data decompression device 115 decompresses the compressed data corresponding to the read data that is requested to be read from the flash memory 12 by the read commands to obtain the read data. In other words, the memory system 1 of the first embodiment has a data compression and decompression system which compresses and decompresses data.

The ECC circuit 116 executes an error correction process for the compressed data generated by the data compression device 114. More specifically, when a write command is received, the ECC circuit 116 generates an error correction code to detect and correct errors in preparation for a case where errors may occur in future in the compressed data to be written to the flash memory 12. Then, the processor 111 is configured to write the error correction code to the flash memory 12 via the memory interface circuit 113. In other words, the processor 111 is configured to write data based on the compressed data generated by the data compression device 114, to the flash memory 12 via the memory interface circuit 113. In addition, when receiving a read command from the host 2, the processor 111 reads data based on the received read command, from the flash memory 12, via the memory interface circuit 113. The ECC circuit 116 executes the error correction process on the read data. In other words, the ECC circuit 116 checks whether or not an error occurs in the compressed data read from the flash memory 12, by using the error correction code, and, if an error is detected, corrects the error. The read data which is subjected to the error correction process is input to the decompression device 115 as compressed data by the processor 111, and the decompression device 115 decompresses the input compressed data. The processor 111 sends the decompressed data to the host 2 in response to the read command from the host 2. In other words, the processor 111 is configured to decompress data based on data read from the flash memory 12 and to send the decompressed data to the host 2, in response to the read command from the host 2.

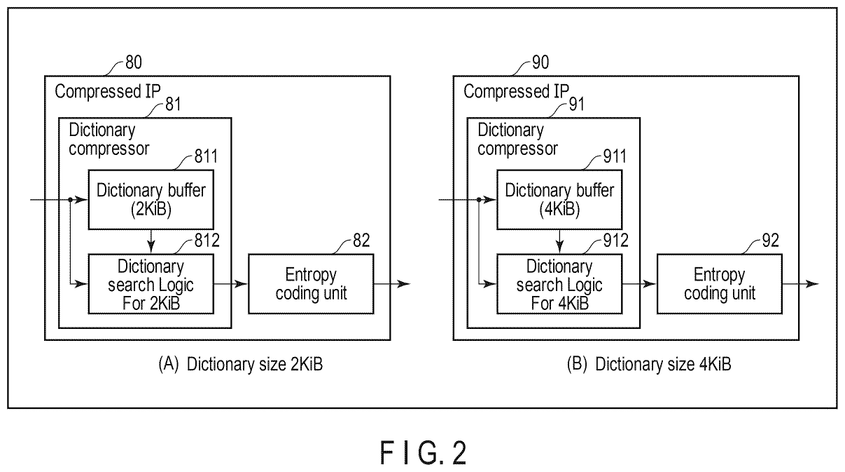

FIG. 2 is a view showing a comparative example to illustrate increasing a circuit scale of a dictionary compressor as a dictionary size is increased to improve a compression efficiency of the dictionary compressor.

FIG. 2(A) shows an example of a configuration of a compressed intellectual property (IP) 80 that includes a dictionary compressor 81 with a dictionary size of 2 KiB.

The dictionary compressor 81 includes a dictionary buffer 811 buffering previously input data and a dictionary search logic 812 searching for data which matches the currently input data from the dictionary buffer 811. The dictionary buffer 811 has a capacity which enables past 2 KiB of previously input data to be buffered. In addition, the dictionary search logic 812 has the ability to search for data which matches the current input data from 2 KiB of previously input data buffered in the dictionary buffer 811.

The compressed IP 80 further includes an entropy coding unit 82 which executes entropy coding on the dictionary compression results output from the dictionary compressor 81.

In contrast, FIG. 2(B) shows an example of a configuration of a compressed IP 90 that includes a dictionary compressor 91 with a dictionary size of 4 KiB. The dictionary buffer 911 of the compressed IP 90 has a capacity which enables 4 KiB of previously input data to be buffered. In addition, a dictionary search logic 912 has the ability to search for data which matches the current input data from 4 KiB of previously input data buffered in the dictionary buffer 811.

The compressed IP 90 further includes an entropy coding unit 92 which executes entropy coding on the dictionary compression results output from a dictionary compressor 91.

As is clarified from comparison between the dictionary buffer 811 and the dictionary search logic 812 of the dictionary compressor 81 in the compressed IP 80 in FIG. 2(A) and the dictionary buffer 911 and the dictionary search logic 912 of the dictionary compressor 91 in the compressed IP 90 in FIG. 2(B), increasing the dictionary size of the dictionary compressor, for example from 2 KiB to 4 KiB, in order to improve the compression efficiency of the dictionary compressor results in an increase in the circuit scale of the dictionary compressor.

In contrast, the data compression device 114 in the memory system 1 of the first embodiment achieves an increase in the dictionary size by diverting existing resources without causing an increase in the circuit scale of the dictionary compressor. This point will be described below in detail.

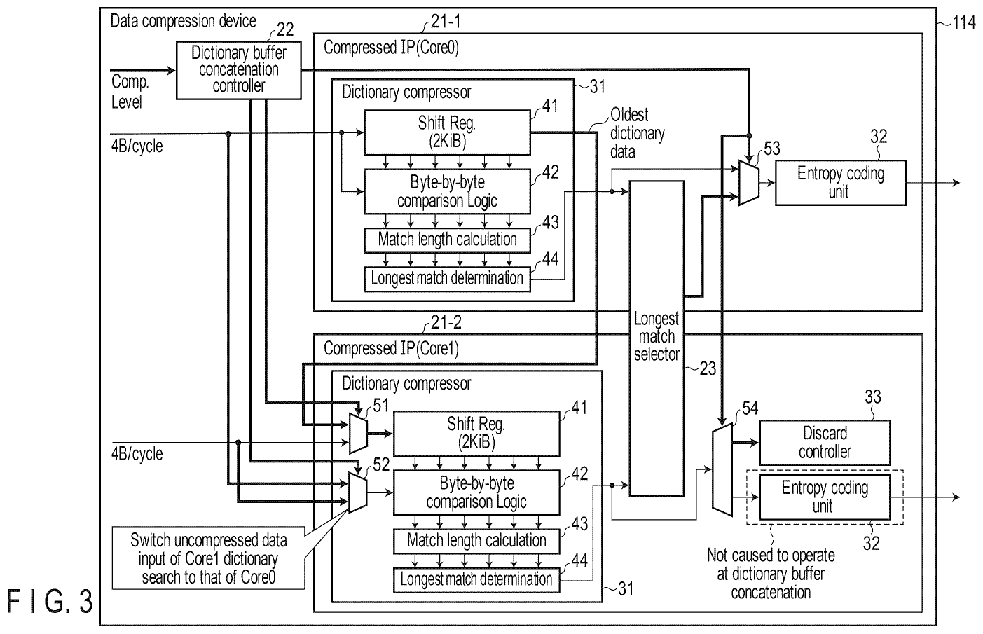

FIG. 3 is a view showing an example of a configuration of the data compression device 114 in the memory system 1 of the first embodiment.

The data compression device 114 of the first embodiment includes two compressed IP (Core0 and Core1) 21. Subscripts (-1 and -2) are used if the compressed IP 21 need to be distinguished in the following descriptions, and the subscripts are omitted if they do not need to be distinguished. Subscripts may also be used for other components that exist in multiple parts.

The compressed IP 21 entropy-encodes the dictionary compression results output by the dictionary compressor of LZ77 method, by an entropy coding unit 32. The entropy encoding method is, for example, Huffman encoding.

A dictionary compressor 31 is, for example, dictionary compression hardware (HW) with a dictionary size of 2 KiB and an input throughput of 4 Bytes/cycle, and includes a 2 KiB shift register 41, a byte-by-byte comparison unit 42, a match length calculation unit 43, and a longest match determination unit 44. The shift register 41 is a dictionary buffer that buffers (stores) the data previously input to the dictionary compressor 31, such as the dictionary buffer 811 in FIG. 2(A) and the dictionary buffer 911 in FIG. 2(B). Then, if data is input to the dictionary compressor 31 after that, the shift register 41 is used when the byte-by-byte comparison unit 42 searches for data which matches the input data, in the dictionary data stored in the shift register 41.

When 4 bytes of uncompressed data are input to the dictionary compressor 31 in each cycle, the dictionary compressor 31 writes the input uncompressed data to the shift register 41. The uncompressed data written to the shift register 41 is treated as dictionary data. The byte-by-byte comparison unit 42 compares the uncompressed data stored in the shift register 41 with a size of a maximum of 2 KiB with the 4-byte input uncompressed data. Next, in the match length calculation unit 43, calculation of the match length for all match distances, which are the match distances, i.e., the distances from certain uncompressed data in the input uncompressed data to certain uncompressed data in the uncompressed data held in the shift register 41 is executed based on the comparison results of the byte comparison unit 42. Finally, the longest match length among the match lengths of all the match distances is selected in the longest match determination unit 44. The shift register 41 is shifted 4 bytes per cycle in a direction of pushing out the previously input data, and the input uncompressed data is written in empty 4 bytes.

The dictionary buffer concatenation controller 22 controls the connection between the shift register 41 of the dictionary compressor 31 of the compressed IP (Core0) 21-1 and the shift register 41 of the dictionary compressor 31 of the compressed IP (Core1) 21-2, and controls the input of uncompressed data to the compressed IP (Core1) 21-2, based on the compression level input to the data compression device 114. The compression level is a value indicating the level among predetermined number of levels, of the compression efficiency requested by the host 2 to the memory controller 11.

If the compression level is less than a predetermined threshold value, the dictionary buffer concatenation controller 22 controls the compressed IP (Core0) 21-1 and the compressed IP (Core1) 21-2 to operate independently. In other words, the shift register 41 of the dictionary compressor 31 of the compressed IP (Core0) 21-1 is not connected to the shift register of the dictionary compressor 31 of the compressed IP (Core1) 21-2, and separate uncompressed data is input to each of the compressed IP (Core0) 21-1 and the compressed IP (Core1) 21-2.

As a result, the compressed IP (Core0) 21-1 and the compressed IP (Core1) 21-2 can operate in parallel, and the data compression device 114 provides two compressed IP with a 4-byte/cycle, 2-KiB dictionary size as the first mode, and the overall input throughput of the data compression device 114 becomes 8 bytes/cycle.

In contrast, when the compression level is above a predetermined threshold, the dictionary buffer concatenation controller 22 controls the shift register 41 of the compressed IP (Core0) 21-1 and the shift register 41 of the compressed IP (Core1) 21-2 to operate as a single dictionary buffer. The dictionary buffer concatenation controller 22 has used the input to the shift register 41 of the dictionary compressor 31 of the compressed IP (Core1) 21-2 as input uncompressed data until the shift register 41 of the compressed IP (Core0) 21-1 and the shift register 41 of the compressed IP (Core1) 21-2 are concatenated to each other. If the compression level is more than or equal to a predetermined threshold value, the dictionary buffer concatenation controller 22 concatenates the shift register 41 of the compressed IP (core 0) 21-1 and the shift register 41 of the compressed IP (core 1) 21-2, and switches the input to the shift register 41 of the dictionary compressor 31 of the compressed IP (Core1) 21-2 to the oldest dictionary data that has been pushed out of the shift register 41 of the dictionary compressor 31 of the compressed IP (Core0) 21-1. More specifically, the dictionary buffer concatenation controller 22 controls the switch 51.

In addition, the dictionary buffer concatenation controller 22 switches the input to the byte-by-byte comparison unit 42 of the dictionary compressor 31 of the compressed IP (Core1) 21-2 from the uncompressed data that is the input to the compressed IP (Core1) 21-2 to the uncompressed data that is the input to the compressed IP (Core0) 21-1. More specifically, the dictionary buffer concatenation controller 22 controls the switch 52.

The match length of the match output from the longest match determination unit 44 of the dictionary compressor 31 of the compressed IP (Core0) 21-1 is compared with the match length of the match output from the longest match determination unit 44 of the dictionary compressor 31 of the compressed IP (Core1) 21-2 by the longest match selector 23. The longest match is selected by the longest match selector 23, and is input to the entropy coding unit 32 of the compressed IP (Core0) 21-1 under the control of the switch 53 by the dictionary buffer concatenation controller 22. In addition, in this case, the output of the longest match determination unit 44 of the compressed IP (Core1) 21-2 is switched to be supplied to the discard controller 33, under the control of the switch 54 by the dictionary buffer concatenation controller 22, and the entropy coding unit 32 of the compressed IP (Core1) 21-2 does not operate. In other words, the dictionary buffer concatenation controller 22 switches the output of the longest match determination unit 44 of the compressed IP (Core1) 21-2 to be supplied to the discard controller 33, by controlling the switch 54, and controls the entropy coding unit 32 of the compressed IP (Core1) 21-2 not to operate. In other words, the dictionary buffer concatenation controller 22 sets the entropy coding unit 32 of the compressed IP (Core1) 21-2, which is in operation by being supplied with the output of the longest match determination unit 44 of the compressed IP (Core1) 21-2, in a non-operated state by cutting off the input to the entropy coding unit 32 of the compressed IP (Core1) 21-2.

As a result, the shift registers 41 of the compressed IP (Core0) 21-1 and the compressed IP (Core1) 21-2 are concatenated to form a 4 KiB dictionary and, accordingly, the byte-by-byte comparison unit 42, the match length calculation unit 43, and the longest match determination unit 44 are also concatenated to obtain the match search results for the 4 KiB dictionary.

As a result, the data compression device 114 provides one compressed IP with a 4-byte/cycle and 4-KiB dictionary size as the second mode, and the overall input throughput of the data compression device 114 becomes 4 bytes/cycle. The input throughput at concatenation of the dictionary buffers is halved compared to that in a case where the dictionary buffers are not concatenated but, instead, increase in the compression ratio can be expected by doubling the dictionary size. In addition, since this method can be achieved by diverting existing components, the increase in circuit size caused by the increase in dictionary size can also be suppressed.

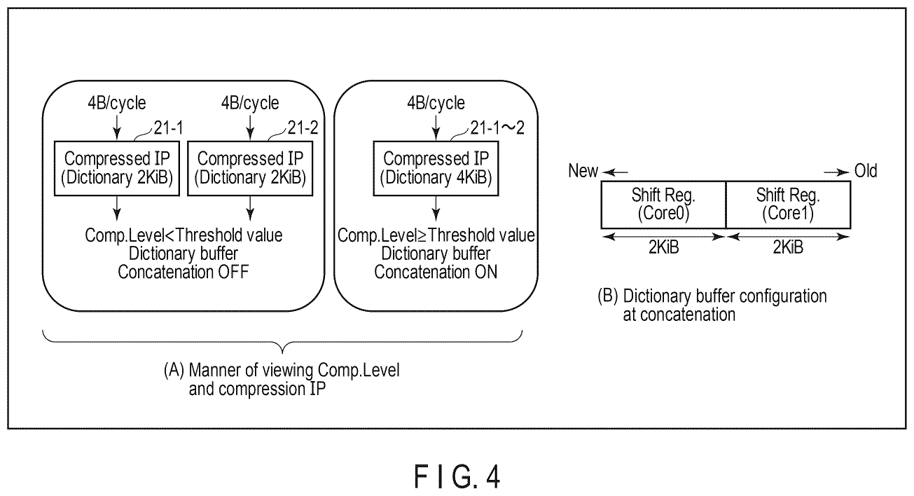

FIG. 4 is a view showing both a manner of viewing a compressed IP 21 with and without the dictionary buffer concatenation in the data compression device 114 and a configuration of a dictionary buffer in a case where the dictionary buffer concatenation is formed, in the memory system 1 of the first embodiment.

FIG. 4(A) shows a manner of viewing the compressed IP 21 with and without dictionary buffer concatenation, which is determined by the compression level.

When the compression level is less than a predetermined threshold value, the dictionary buffer concatenation is not formed (OFF). In this case, each of the two compressed IP 21 operates independently at 4 bytes/cycle and a dictionary size of 2 KiB. In this case, the overall input throughput of the data compression device 114 is 8 bytes/cycle.

In contrast, if the compression level is more than or equal to a predetermined threshold value, the dictionary buffer concatenation is formed (ON). In this case, the two compressed IP 21 cooperate at a 4-byte/cycle and 4-KiB dictionary size. In this case, the overall input throughput of the data compression device 114 is 4 bytes/cycle.

FIG. 4(B) shows an example of the dictionary buffer configuration in a case where the dictionary buffer concatenation is formed (ON). When the dictionary buffer concatenation is formed (ON), the uncompressed data is first input to the shift register 41 of the dictionary compressor 31 of the compressed IP (Core0) 21-1. The uncompressed data is shifted 4 bytes per cycle, and is input to the shift register 41 of the dictionary compressor 31 of the compressed IP (Core1) 21-2 when pushed out of the shift register 41 of the dictionary compressor 31 of the compressed IP (Core0) 21-1.

As described above, the data compression device 114 in the memory system 1 of the first embodiment can increase the dictionary size by diverting the existing resource of the shift register 41 of the dictionary compressor 31 of the compressed IP (Core1) 21-2.

### Second Embodiment

Next, a second embodiment will be described.

The second embodiment is also an example of a memory system implemented as an SSD, similarly to the first embodiment. The same components as those in the first embodiment are denoted by the same reference numerals and their descriptions are omitted.

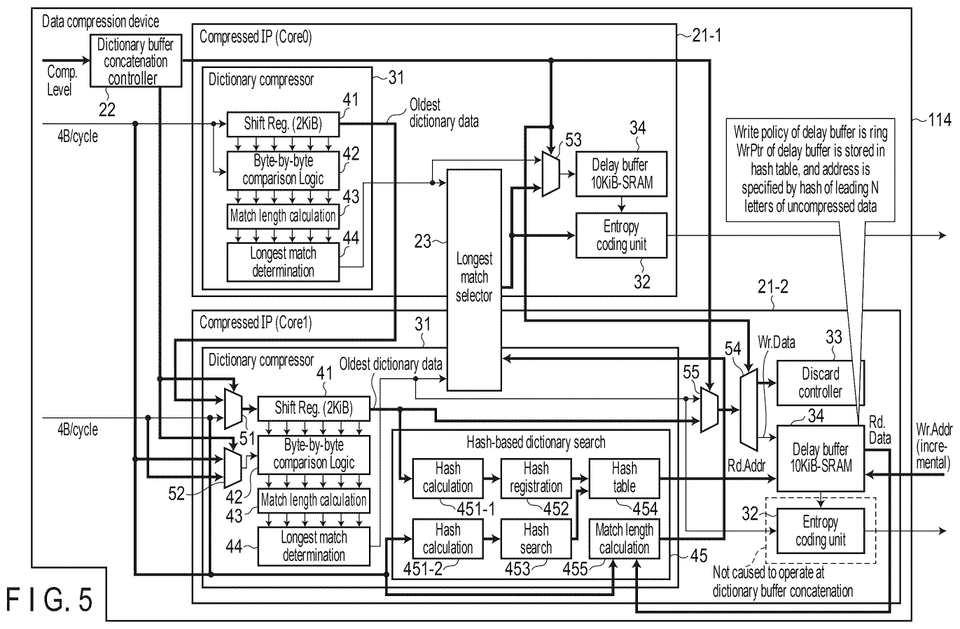

FIG. 5 is a view showing an example of a configuration of a data compression device 114 in a memory system 1 of the second embodiment.

In the data compression device 114 of the second embodiment, a shift register 41 of a dictionary compressor 31 of compressed IP (Core0) 21-1 is concatenated to a shift register 41 of a dictionary compressor 31 of compressed IP (Core1) 21-2. Furthermore, a delay buffer 34 of the compressed IP (Core1) 21-2 in which an entropy coding unit 32 does not operate at concatenation of the dictionary buffers is diverted (used) as a dictionary buffer. As a result, the second embodiment can increase the dictionary size more than the first embodiment.

The entropy coding unit 32 uses dynamic Huffman coding (i.e., Huffman coding method generating a code table based on the appearance frequency of input symbols) as the entropy coding method, and includes a delay buffer 34 configured with, for example, 10 KiB-SRAM in each of the compressed IP (Core0) 21-1 and the compressed IP (Core0) 21-2 for the purpose of buffering input symbols during the cycle period of the code table generation.

The symbols of the dictionary compression results are buffered in the delay buffer 34. The entropy coding unit 32 counts the appearance frequency of each symbol included in a block of a predetermined size, and then constructs a Huffman tree based on the obtained appearance frequency to generate an encoding table. The dictionary compressor 31 of the compressed IP (Core0) 21-1 has the same configuration as the dictionary compressor 31 of the first embodiment.

The dictionary compressor 31 of the compressed IP (Core0) 21-2 includes a hash-based dictionary search unit 45 in addition to the configuration of the dictionary compressor 31 of the first embodiment. The operations of the dictionary buffer concatenation controller 22 in the second embodiment are as follows.

If the compression level is less than a predetermined threshold value, the dictionary buffer concatenation controller 22 controls the compressed IP (Core0) 21-1 and the compressed IP (Core1) 21-2 to operate independently. In other words, the shift register 41 of the dictionary compressor 31 of the compressed IP (Core0) 21-1 is not connected to the shift register of the dictionary compressor 31 of the compressed IP (Core1) 21-2, and separate uncompressed data is input to each of the compressed IP (Core0) 21-1 and the compressed IP (Core1) 21-2. In addition, the hash-based dictionary search unit 45 does not operate.

The inputs to the delay buffer 34 of the compressed IP (Core0) 21-1 and the delay buffer 34 of the compressed IP (Core0) 21-2 are the outputs of the longest match determination units 44 in the compressed IP (Core0) 21-1 and the compressed IP (Core1) 21-2, respectively.

As a result, similarly to the first embodiment, the compressed IP (Core0) 21-1 and the compressed IP (Core0) 21-2 can operate in parallel, and the data compression device 114 provides two compressed IP with a 4-byte/cycle, 2-KiB dictionary size as the first mode, and the overall input throughput of the data compression device 114 becomes 8 bytes/cycle.

In contrast, if the compression level is more than or equal to a predetermined threshold value, the dictionary buffer concatenation controller 22 concatenates and controls the shift register 41 of the compressed IP (Core0) 21-1, the shift register 41 of the compressed IP (Core1) 21-2, and the delay buffer 34 of the compressed IP (Core1) 21-2 to operate as a single dictionary buffer. The dictionary buffer concatenation controller 22 switches the input to the shift register 41 of the dictionary compressor 31 of the compressed IP (Core1) 21-1 from the uncompressed data input to the oldest dictionary data pushed out of the shift register 41 of the dictionary compressor 31 of the compressed IP (Core0) 21-1. More specifically, the dictionary buffer concatenation controller 22 controls the switch 51.

In addition, the dictionary buffer concatenation controller 22 switches the input to the byte-wise comparison unit 42 of the dictionary compressor of the compressed IP (Core1) 21-2 from the uncompressed data that is the input to the compressed IP (Core1) 21-2 to the uncompressed data that is the input to the compressed IP (Core0) 21-1. More specifically, the dictionary buffer concatenation controller 22 controls the switch 52.

Furthermore, the dictionary buffer concatenation controller 22 switches the input to the delay buffer 34 of the compressed IP (Core1) 21-2 from the output result of the longest match determination unit 44 of the compressed IP (Core1) 21-2 to the oldest dictionary data pushed out of the shift register 41 of the dictionary compressor 31 of the compressed IP (Core1) 21-2. More specifically, the dictionary buffer concatenation controller 22 controls the switches 54 and 55.

The write policy for the delay buffer 34 of the compressed IP (Core1) 21-2 is a ring buffer. The hash-based dictionary search unit 45 executes a hash-based dictionary search process on the dictionary data written to the delay buffer 34.

The longest match selector 23 compares the output of the longest match determination unit 44 of the compressed IP (Core0) 21-1, the output of the longest match determination unit 44 of the compressed IP (Core1) 21-2, and an output of a match length calculation unit 455 of the hash-based dictionary search unit 45, and outputs the match with the longest match length to both the delay buffer 34 and the entropy coding unit 32 of the compressed IP (Core0) 21-1. In addition, the uncompressed data which is the input to the compressed IP (Core0) 21-1 is input to the hash-based dictionary search unit 45 of the compressed IP (Core1) 21-2.

The hash-based dictionary search unit 45 includes a hash calculation unit 451-1, a hash calculation unit 451-2, a hash registration unit 452, a hash search unit 453, a hash table unit 454, and a match length calculation unit 455. The hash table unit 454 has an array with the number of elements=H, and a 14-bit (≈ceil(1024×10)) delay buffer address and D 1-bit flags indicating validity/invalidity of the delay buffer address are stored in each entry in the array. For example, H=512 and D=4. When data is written to the delay buffer 34 of the compressed IP (Core1) 21-2, at the dictionary buffer concatenation operation, the hash calculation unit 451-1 calculates a hash value based on at least a part of the data written to the delay buffer 34. The hash value is calculated based on, for example, the first 3 bytes of the data written to the delay buffer 34. The hash registration unit 452 determines index (0 to H−1) of the array in the hash table unit based on the hash value, and writes the delay buffer address of the data written to the delay buffer 34 to the entry corresponding to the determined index. The D delay buffer addresses included in the array entry are updated according to the FIFO policy. When the uncompressed data is input to the hash-based dictionary search unit 45, the hash calculation unit 451-2 calculates a hash value based on at least a part of the uncompressed data input. The method of calculating the hash value is the same as the method of calculating the hash value used for the hash registration unit 452. The hash search unit 453 determines the index (0 to H−1) of the array in the hash table unit 454 based on the hash value, and reads the entry corresponding to the determined index from the array. At least some of D′ (D′≤D) delay buffer addresses indicated to be valid by the flag among the D delay buffer addresses included in the entry read from the array, are selected, and dictionary data is read from the delay buffer 34. The selection criterion is, for example, the order of shorter match distance (i.e., the order of delayed timing of being pushed in the FIFO), but is not limited to this. The selection may be executed by additionally storing a part of the hash value in addition to the delay buffer address and the valid/invalid flags, as an array entry, and comparing this value with the hash value input to the hash search unit 453. The read dictionary data is compared with the uncompressed data input to the hash-based dictionary search unit 45 in the match length calculation unit 455, and the match length is calculated.

The output of the longest match determination unit 44 of the compressed IP (Core0) 21-1, the output of the longest match determination unit 44 of the compressed IP (Core1) 21-2, and the output of the match length calculation unit 455 of the hash-based dictionary search unit 45 are compared in the longest match selector 23, and the match with the longest match length is selected and input to the entropy coding unit 32 of the compressed IP (Core0) 21-1. The entropy coding unit 32 of the compressed IP (Core1) 21-2 does not operate.

As a result, the shift register 41 of the compressed IP (Core0) 21-1, the shift register 41 of the compressed IP (Core1) 21-2, and the delay buffer 34 of the compressed IP (Core1) 21-2 are concatenated to constitute a 14 KiB dictionary, and the result of the match search for the 14 KiB dictionary is obtained. As a result, the data compression device 114 provides one compressed IP 21 with a 4-byte/cycle and 14-KiB dictionary size, in the second mode, and the overall input throughput of the data compression device 114 becomes 4 bytes/cycle. In comparison with the first embodiment, the input throughput is the same, the dictionary size is increased by 10 KiB, and the improvement in compression ratio can be expected.

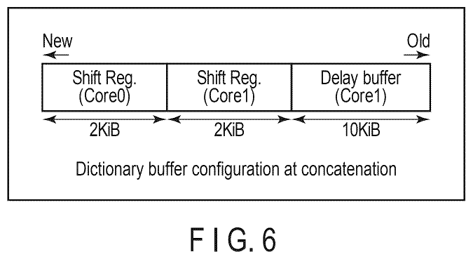

FIG. 6 is a view showing a configuration of a dictionary buffer in a case where dictionary buffer concatenation of the data compression device is formed, in the memory system of the second embodiment.

If the dictionary buffer concatenation is formed, uncompressed data is first input to the shift register 41 of the dictionary compressor 31 of the compressed IP (Core0) 21-1. The uncompressed data is shifted 4 bytes per cycle, and is input to the shift register 41 of the dictionary compressor 31 of the compressed IP (Core1) 21-2 when pushed out of the shift register 41 of the dictionary compressor 31 of the compressed IP (Core0) 21-1. Furthermore, when the uncompressed data is pushed out of the shift register 41 of the dictionary compressor 31 of the compressed IP (Core1) 21-2, the uncompressed data is input to the delay buffer 34 of the compressed IP (Core1) 21-2.

As described above, the data compression device 114 in the memory system 1 of the second embodiment can increase the dictionary size by diverting the existing resources, i.e., the shift register 41 of the dictionary compressor 31 of the compressed IP (Core1) 21-2 and the delay buffer 34 of the compressed IP (Core1) 21-2.

### Third Embodiment

Next, a third embodiment will be described.

The third embodiment is also an example of a memory system implemented as an SSD, similarly to the first and second embodiments. The same components as those in the first and second embodiments are denoted by the same reference numerals and their descriptions are omitted.

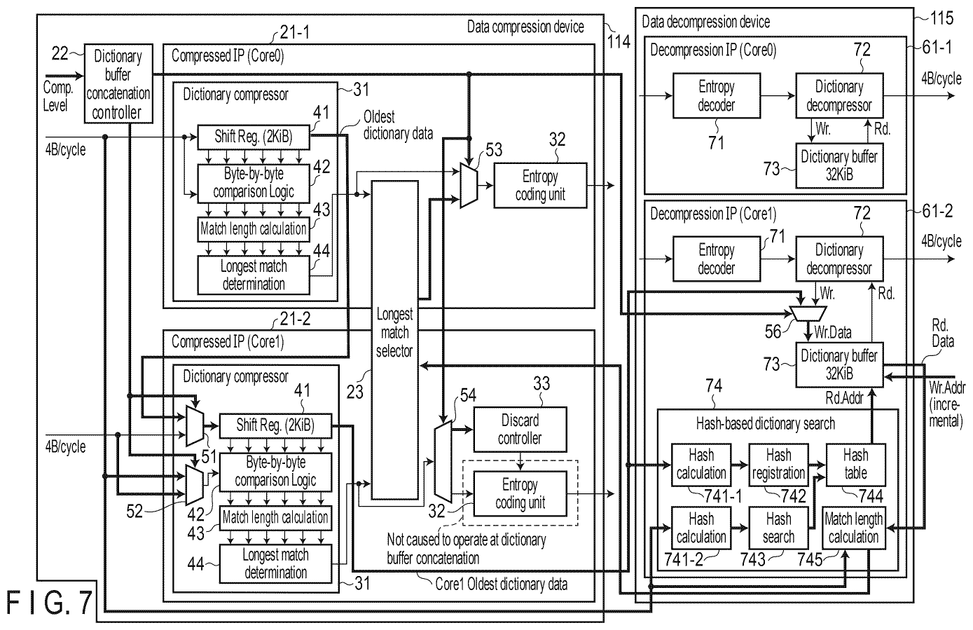

FIG. 7 is a view showing an example of a configuration of a data compression device 114 and a data decompression device 115 in a memory system 1 of the third embodiment.

In the data compression device 114 of the third embodiment, the data decompression device 115 is applied as an existing resource which is diverted to increase the dictionary size. The data decompression device 115 includes two decompressed IP 61 with a decompression throughput of 4 Bytes/cycle. More specifically, the data decompression device 115 includes decompressed IP (Core0) 61-1 and decompressed IP (Core1) 61-2.

The decompressed IP 61 includes an entropy decoding unit 71, a dictionary decompressor 72, and a dictionary buffer 73 of 32 KiB-SRAM. In addition, the decompressed IP (Core1) 61-2 includes a hash-based dictionary search unit 74 similar to the hash-based dictionary search unit 45 of the second embodiment.

In the third embodiment, the dictionary buffer 73 for dictionary decompression, which is included in the decompressed IP (Core1) 61-2 is diverted as the dictionary buffer of the compressed IP 21, thereby increasing the dictionary size at the compression.

If the compression level is less than a predetermined threshold value, the dictionary buffer concatenation controller 22 controls such that the compressed IP (Core0) 21-1 and the compressed IP (Core1) 21-2 of the data compression device 114, and the decompressed IP (Core0) 61-1 and the decompressed IP (Core1) 61-2 of the data decompression device 115 operate independently of each other. In other words, the shift register 41 of the dictionary compressor 31 of the compressed IP (Core0) 21-1 of the data compression device 114 is not connected to the shift register 41 of the dictionary compressor 31 of the compressed IP (Core1) 21-2 of the data compression device 114, and separate uncompressed data is input to the compressed IP (Core0) 21-1 and the compressed IP (Core1) 21-2, and separate compressed data is input to decompressed IP (Core0) 61-1 and decompressed IP (Core1) 61-2 of data decompression device 115. In addition, the hash-based dictionary search unit 74 of the decompressed IP (Core1) 61-2 of the data decompression device 115 does not operate.

As a result, the compressed IP (Core0) 21-1 and the compressed IP (Core1) 21-2 of the data compression device 114 can operate in parallel, and the decompressed IP (Core0) 61-1 and the decompressed IP (Core1) 61-2 of the data decompression device 115 can operate in parallel. The data compression device 114 provides two compressed IP 21 with a 4-byte/cycle and 2-KiB dictionary size, in the first mode, and the overall input throughput of the data compression device 114 becomes 8 bytes/cycle. The data decompression device 115 provides two decompressed IP 61 with 4 Byte/cycle and a dictionary size of 32 KiB, and an output throughput of the overall data decompression device 115 is 8 bytes/cycle.

In contrast, if the compression level is more than or equal to a predetermined threshold value, the dictionary buffer concatenation controller 22 controls to concatenate the shift register 41 of the compressed IP (Core0) 21-1 of the data compression device 114, the shift register 41 of the compressed IP (Core1) 21-2, and the dictionary buffer 73 of the decompressed IP (Core1) 21-2 of the data decompression device 115 and to operate as a single dictionary buffer. The dictionary buffer concatenation controller 22 switches the input to the shift register 41 of the dictionary compressor 31 of the compressed IP (Core0) 21-1 of the data compression device 114 from the uncompressed data input to the oldest dictionary data pushed out of the shift register 41 of the dictionary compressor 31 of the compressed IP (Core0) 21-1 of the data compression device 114. More specifically, the dictionary buffer concatenation controller 22 controls the switch 51.

In addition, the dictionary buffer concatenation controller 22 switches the input to the byte-wise comparison unit 42 of the dictionary compressor 31 of the compressed IP (Core1) 21-2 of the data compression device 114 from the uncompressed data input that is the input to the compressed IP (Core1) 21-2 of the data compression device 114 to the uncompressed data that is the input to the compressed IP (Core0) 21-1 of the data compression device 114. More specifically, the dictionary buffer concatenation controller 22 controls the switch 52.

Furthermore, the dictionary buffer concatenation controller 22 switches the input to the delay buffer 73 of the compressed IP (Core1) 61-2 from the output result of the dictionary decompressor 72 of the decompressed IP (Core1) 61-2 of the data decompression device 115 to the oldest dictionary data pushed out of the shift register 41 of the dictionary compressor 31 of the compressed IP (Core1) 21-2 of the data compression device 114. More specifically, the dictionary buffer concatenation controller 22 controls the switch 56.

At this time, the entropy decoding unit 71 and the dictionary decompressor 72 of the decompressed IP (Core1) 61-2 of the data decompression device 115 do not operate.

The writing policy for the dictionary buffer 73 of the decompressed IP (Core1) 61-2 of the data decompression device 115 is a ring buffer. The hash-based dictionary search unit 74 executes a hash-based dictionary search process for the dictionary data written to the dictionary buffer 73 of the decompressed IP (Core1) 61-2 of the data decompression device 115.

The longest match selector 23 compares the output of the longest match determination unit 44 of the dictionary compressor 31 of the compressed IP (Core0) 21-1 of the data compression device 114, the output of the longest match determination unit 44 of the dictionary compressor 31 of the compressed IP (Core1) 21-2 of the data compression device 114, and the output of the match length calculation unit 745 of the hash-based dictionary search unit 74 of the decompressed IP (Core1) 61-2 of the data decompression device 115, and outputs the match with the longest match length to both the hash-based dictionary search unit 74 and the entropy coding unit of the compressed IP (Core0) 21-1 of the data compression device 114. In addition, the uncompressed data which is the input to the compressed IP (Core0) 21-1 is input to the hash-based dictionary search unit 74 of the decompression device 115.

Accordingly, the shift register 41 of the compressed IP (Core0) 21-1 of the data compression device 114, the shift register 41 of the compressed IP (Core1) 21-2 of the data compression device 114, and the dictionary buffer 73 of the decompressed IP (Core1) 61-2 of the data decompression device 115 are concatenated to constitute a 36 KiB dictionary, and the result of the match search for the 36 KiB dictionary is obtained.

As a result, the data compression device 114 provides one compressed IP 21 with a 4-byte/cycle and 36-KiB dictionary size, in the second mode, and the overall input throughput of the data compression device 114 becomes 4 bytes/cycle. In addition, the output throughput of the overall data decompression device 115 is 8 bytes/cycle when the dictionary buffer is not concatenated in the data compression device 114, and 4 bytes/cycle when the dictionary buffer is concatenated. In comparison with the first embodiment, the input throughput of the data compression device 114 is the same, the output throughput of the data decompression device 115 is halved, the dictionary size is increased by 24 KiB, and the improvement in compression ratio can be expected.

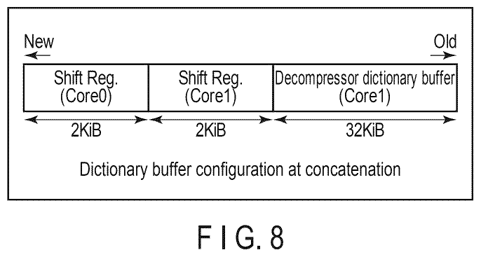

FIG. 8 is a view showing a configuration of a dictionary buffer in a case where dictionary buffer concatenation of the data compression device 114 is formed, in the memory system 1 of the third embodiment.

If the dictionary buffer concatenation is formed, the uncompressed data is first input to the shift register 41 of the dictionary compressor 31 of the compressed IP (Core0) 21-1 of the data compression device 114. The uncompressed data is shifted 4 bytes per cycle, and is input to the shift register 41 of the dictionary compressor 31 of the compressed IP (Core1) 21-2 of the data compression device 114 when pushed out of the shift register 41 of the dictionary compressor 31 of the compressed IP (Core0) 21-1 of the data compression device 114. Furthermore, the uncompressed data is input to the dictionary buffer 73 of the decompressed IP (Core0) 61-2 of the data decompression device 115 when pushed out of the shift register 41 of the dictionary compressor 31 of the compressed IP (Core0) 21-2 of the data compression device 114.

As described above, the data compression device 114 in the memory system 1 of the third embodiment can increase the dictionary size by diverting the existing resources, i.e., the shift register 41 of the dictionary compressor 31 of the compressed IP (Core1) 21-2 of the data compression device 114 and the dictionary buffer 73 of the decompressed IP (Core1) 61-2 of the data decompression device 115.

### Fourth Embodiment

Next, a fourth embodiment will be described.

The fourth embodiment is also an example of a memory system implemented as an SSD, similarly to the first to third embodiments. The same components as those in the first to third embodiments are denoted by the same reference numerals and their descriptions are omitted.

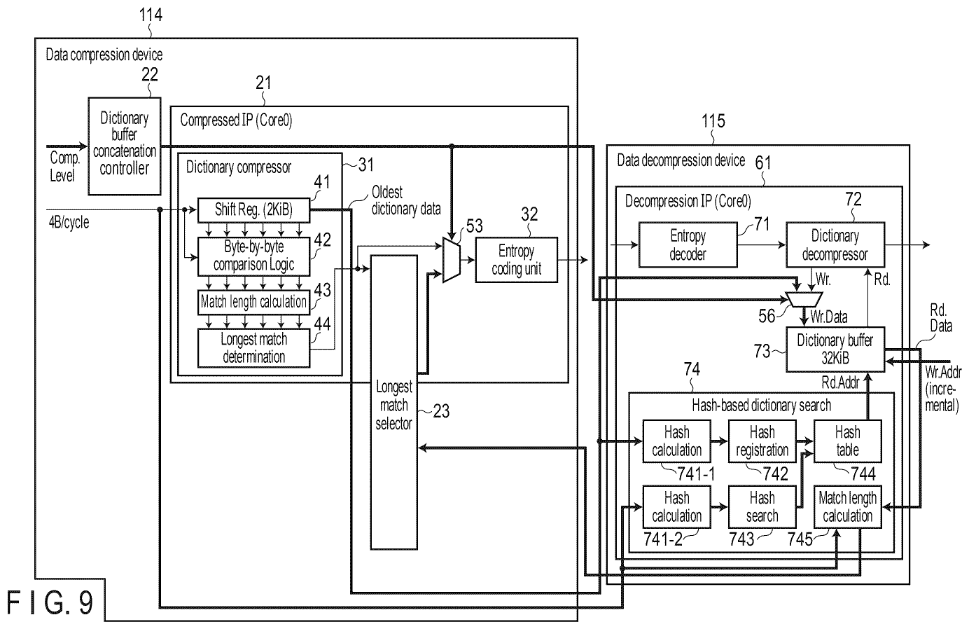

FIG. 9 is a view showing an example of a configuration of a data compression device 114 and a data decompression device 115 in a memory system 1 of the fourth embodiment.

As shown in FIG. 9, in the fourth embodiment, the data compression device 114 includes one compressed IP (Core0) 21. In addition, the data decompression device 115 also includes one decompressed IP (Core0) 61. The decompressed IP (Core0) 61 increases a hash-based dictionary search unit 74.

In the fourth embodiment, the dictionary buffer concatenation controller 22 of the compressed IP (Core0) 21 of the data compression device 114, in the second mode, concatenates the shift register 41 of the compressed IP (Core0) 21 of the data compression device 114 and the dictionary buffer 73 of the decompressed IP (Core0) 61 of the data decompression device 115 to constitute a 34 KiB dictionary buffer.

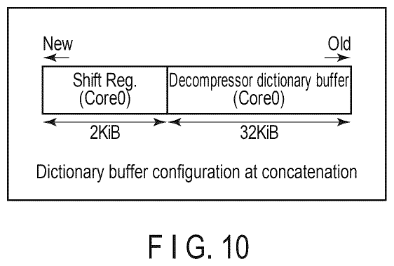

FIG. 10 is a view showing a configuration of a dictionary buffer in a case where dictionary buffer concatenation of the data compression device 114 is formed, in the memory system 1 of the fourth embodiment.

If the dictionary buffer concatenation is formed, the uncompressed data is first input to the shift register 41 of the dictionary compressor 31 of the compressed IP (Core0) 21 of the data compression device 114. The uncompressed data is shifted 4 bytes per cycle, and is input to the dictionary buffer 73 of the decompressed IP (Core0) 61 of the data decompression device 115 when pushed out of the shift register 41 of the dictionary compressor 31 of the compressed IP (Core0) 21 of the data compression device 114.

As described above, even in the configuration that the data compression device 114 includes only one compressed IP (Core0) 21 and the data decompression device 115 includes only one decompressed IP (Core0) 61, the data compression device 114 in the memory system 1 of the fourth embodiment can increase the dictionary size by diverting the existing resource of the dictionary buffer 73 of the decompressed IP (Core0) 61 of data decompression device 115.

### Fifth Embodiment

Next, a fifth embodiment will be described.

The fifth embodiment is also an example of a memory system implemented as an SSD, similarly to the first to fourth embodiments. The same components as those in the first to fourth embodiments are denoted by the same reference numerals and their descriptions are omitted.

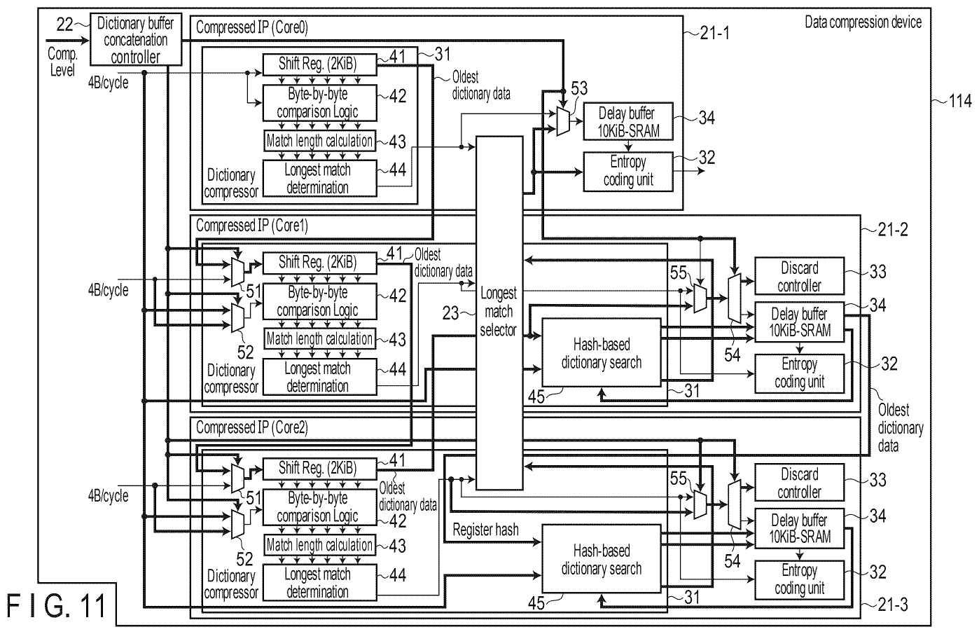

FIG. 11 is a view showing an example of a configuration of the data compression device 114 in the memory system 1 of the fifth embodiment.

As shown in FIG. 11, in the fifth embodiment, the data compression device 114 includes three compressed IP (Core0, Core1, and Core2) 21 (-1 to 3). The entropy coding unit 32 of each compressed IP 21 is a dynamic Huffman code, similarly to the second embodiment, and uses a delay buffer 34 configured with 10 KiB-SRAM. In the fifth embodiment, the dictionary buffer concatenation controller 22 of the data compression device 114, in the second mode, concatenates the shift register 41 of the compressed IP (Core0) 21-1, the shift register 41 of the compressed IP (Core1) 21-2, the shift register 41 of the compressed IP (Core 2) 21-3, the delay buffer 34 of the compressed IP (Core1) 21-2, and the delay buffer 34 of the compressed IP (Core2) 21-3 to constitute a 26 KiB dictionary buffer.

When the compression level is more than or equal to a predetermined threshold value, Furthermore, the dictionary buffer concatenation controller 22 switches the input to the shift register 41 of the dictionary compressor 31 of the compressed IP (Core1) 21-2 from the uncompressed data input to the oldest dictionary data pushed out of the shift register 41 of the dictionary compressor 31 of the compressed IP (Core0) 21-1. More specifically, the dictionary buffer concatenation controller 22 controls the switch 51 of the compressed IP (Core1) 21-2.

In addition, the dictionary buffer concatenation controller 22 switches the input to the byte-wise comparison unit 42 of the dictionary compressor 31 of the compressed IP (Core1) 21-2 from the uncompressed data that is the input to the compressed IP (Core1) 21-2 to the uncompressed data input that is the input to the compressed IP (Core0) 21-1. More specifically, the dictionary buffer concatenation controller 22 controls the switch 52 of the compressed IP (Core1) 21-2.

Furthermore, the dictionary buffer concatenation controller 22 switches the input to the shift register 41 of the dictionary compressor 31 of the compressed IP (Core2) 21-3 from the uncompressed data input to the oldest dictionary data pushed out of the shift register 41 of the dictionary compressor 31 of the compressed IP (Core1) 21-2. More specifically, the dictionary buffer concatenation controller 22 controls the switch 51 of the compressed IP (Core2) 21-3.

In addition, the dictionary buffer concatenation controller 22 switches the input to the byte-wise comparison unit 42 of the dictionary compressor 31 of the compressed IP (Core2) 21-3 from the uncompressed data input that is the input to the compressed IP (Core2) 21-3 to the uncompressed data input that is the input to the compressed IP (Core0) 21-1. More specifically, the dictionary buffer concatenation controller 22 controls the switch 52 of the compressed IP (Core2) 21-3.

Furthermore, the dictionary buffer concatenation controller 22 switches the input to the delay buffer 34 of the compressed IP (Core1) 21-2 from the output of the longest match determination unit 44 of the compressed IP (Core1) 21-2 to the oldest dictionary data pushed out of the shift register 41 of the dictionary compressor 31 of the compressed IP (Core2) 21-3. More specifically, the dictionary buffer concatenation controller 22 controls the switches 54 and 55 of the compressed IP (Core1) 21-2.

Furthermore, the dictionary buffer concatenation controller 22 switches the input to the delay buffer 34 of the compressed IP (Core 2) 21-3 from the output of the longest match determination unit 44 of the compressed IP (Core 2) 21-3 to the oldest dictionary data that is overwritten in the delay buffer 34 of the compressed IP (Core1) 21-2.

The longest match selector 23 compares the output of the longest match determination unit 44 of the compressed IP (Core0) 21-1, the output of the longest match determination unit 44 of the compressed IP (Core1) 21-2, the output of the longest match determination unit 44 of the compressed IP (Core 2) 21-3, and the output of the match length calculation unit 455 of the hash-based dictionary search unit 45 of the compressed IP (Core1) 21-2, and the output of the match length calculation unit 455 of the hash-based dictionary search unit 45 of the compressed IP (Core 2) 21-3, and outputs the match with the longest match length to both the delay buffer 34 of the compressed IP (Core0) 21-1 and the entropy coding unit 32 of the compressed IP (Core0) 21-1. In addition, the uncompressed data which is the input to the compressed IP (Core0) 21-1 is input to the hash-based dictionary search unit 45 of the compressed IP (Core1) 21-2 and the hash-based dictionary search unit 45 of the compressed IP (Core 2) 21-3.

Accordingly, the shift registers 41 of the compressed IP (Core0) 21-1, the shift registers 41 of the compressed IP (Core1) 21-2, the shift registers 41 of the compressed IP (Core 2) 21-3, the delay buffers 34 of the compressed IP (Core1) 21-2, and the delay buffer 34 of the compressed IP (Core1) 21-2 are concatenated to constitute a 26 KiB dictionary, and the result of the match search for the 26 KiB dictionary is obtained.

As a result, the data compression device provides one compressed IP 21 with 4-byte/cycle and a dictionary size of 26 KiB, in the second mode, and the overall input throughput of the data compression device 114 is 4 bytes/cycle. In comparison with the first embodiment, the input throughput of the entire data compression device 114 is the same, the dictionary size is increased by 24 KiB, and the improvement in compression ratio can be expected.

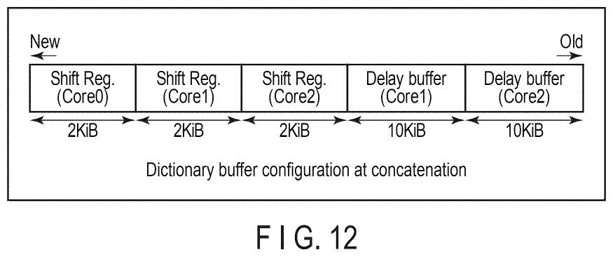

FIG. 12 is a view showing a configuration of a dictionary buffer in a case where dictionary buffer concatenation of the data compression device 114 is formed, in the memory system 1 of the fifth embodiment.

If the dictionary buffer concatenation is formed, uncompressed data is first input to the shift register 41 of the dictionary compressor 31 of the compressed IP (Core0) 21-1. The uncompressed data is shifted 4 bytes per cycle, and is input to the shift register 41 of the dictionary compressor 31 of the compressed IP (Core1) 21-2 when pushed out of the shift register 41 of the dictionary compressor 31 of the compressed IP (Core0) 21-1. Similarly, when the uncompressed data is pushed out of the shift register 41 of the dictionary compressor 31 of the compressed IP (Core1) 21-2, the uncompressed data is input to the shift register 41 of the dictionary compressor 31 of the compressed IP (Core 2) 21-3.

In addition, when the uncompressed data is pushed out of the shift register 41 of the dictionary compressor 31 of the compressed IP (Core2) 21-3, the uncompressed data is input to the delay buffer 34 of the compressed IP (Core1) 21-2. Furthermore, when the uncompressed data is pushed out of the delay buffer 34 of the compressed IP (Core1) 21-1, the uncompressed data is input to the delay buffer 34 of the compressed IP (Core2) 21-3.

As described above, the data compression device 114 in the memory system 1 of the fifth embodiment can further increase the dictionary size by diverting the existing resources, i.e., the shift register 41 of the dictionary compressor 31 of the compressed IP (Core1) 21-2, the shift register 41 of the dictionary compressor 31 of the compressed IP (Core2) 21-3, the delay buffer 34 of the compressed IP (Core1) 21-2, and the delay buffer 34 of the compressed IP (Core 2) 21-3.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A data compression device comprising:
N data compression circuits each including a first dictionary compression circuit, the N being an integer of two or more;
a dictionary buffer concatenation control circuit configured to control switching between a first mode and a second mode, the first mode being a mode in which each of the N data compression circuits operates independently, the second mode being a mode in which the N data compression circuits cooperate; and
a longest match selection circuit configured to select, in the second mode, a dictionary compression result with a longest match length from among dictionary compression results of the N first dictionary compression circuits in the N data compression circuits, wherein
the first dictionary compression circuit includes a dictionary buffer for buffering the uncompressed data to be input and compressed as dictionary data, and
the dictionary buffer concatenation control circuit is configured to
in the first mode,
input the N uncompressed data different from each other to the N data compression circuits, and
in the second mode,
concatenate the N dictionary buffers by storing, when registering the dictionary data to an i-th dictionary buffer out of the N dictionary buffers of the N data compression circuits, oldest dictionary data stored in the i-th dictionary buffer in a (i+1)-th dictionary buffer, the i being an integer of 1 or more and N−1 or less, and
input same uncompressed data to the N data compression circuits.

2. The data compression device of claim 1, wherein
the data compression circuit includes an entropy coding circuit, and
the dictionary buffer concatenation control circuit is configured to
in the first mode,
input dictionary compression results of the N first dictionary compression circuits to the N entropy coding circuits respectively, and
in the second mode,
input the dictionary compression result selected by the longest match selection circuit to the entropy coding circuit of the first data compression circuit out of the N entropy coding circuit, and
set the (N−-1) entropy coding circuits of the second to N-th data compression circuits in a non-operated state.

3. The data compression device of claim 2, wherein
each of the N first dictionary compression circuits is configured to compare the previously input uncompressed data stored in the dictionary buffer with the uncompressed data input thereafter to calculate the dictionary compression result.

4. The data compression device of claim 3, wherein
the dictionary compression result includes a match length and a match distance, the match length being a length of data matching between the uncompressed data input thereafter and the previously input uncompressed data stored in the dictionary buffer, the match distance being a distance from the matching data among the uncompressed data input thereafter to the matching data among the previously input uncompressed data stored in the dictionary buffer.

5. The data compression device of claim 2, wherein
the dictionary buffer concatenation control circuit is configured to set the (N−1) entropy coding circuits of the second to N-th data compression circuits in a non-operated state, by interrupting the input of the dictionary compression result.

6. The data compression device of claim 2, wherein
the entropy coding circuit includes a delay buffer for buffering a symbol of the dictionary compression result of the first dictionary compression circuit,
each of the second to N-th data compression circuits includes a second dictionary compression circuit for executing dictionary compression using the delay buffer of the entropy coding circuit, and
the dictionary buffer concatenation control circuit is configured to, in the second mode,
further concatenate the dictionary buffer and the delay buffer such that
oldest dictionary data in the dictionary buffer of the N-th data compression circuit is shifted to the delay buffer of the second data compression circuit out of the N delay buffers of the N data compression circuits, and that
oldest dictionary data in a delay buffer of a j-th data compression circuit (where j is an integer of 2 or more and N−1 or less) is shifted to a delay buffer of a (j+1)-th data compression circuit, and
input the dictionary compression results of the second dictionary compression circuits of the second to N-th data compression circuits to the longest match selection circuit.

7. The data compression device of claim 6, wherein
the second dictionary compression circuit is configured to execute hash-based dictionary compression on the uncompressed data.

8. A data compression/decompression system, comprising:
the data compression device of claim 1; and
a data decompression device including N data decompression circuits, wherein
the data decompression circuit includes
a dictionary decompression buffer for buffering uncompressed data obtained by decompressing compressed data to be decompressed, as dictionary data, and
a third dictionary compression circuit configured to execute dictionary compression using the dictionary decompression buffer, and
the dictionary buffer concatenation control circuit is configured to, in the second mode,
further concatenate the dictionary buffer and the dictionary decompression buffer such that
oldest dictionary data in the dictionary buffer of the N-th data compression circuit is shifted to the dictionary decompression buffer of the second data decompression circuit out of the N dictionary decompression buffers of the N data decompression circuits, and that
oldest dictionary data in a dictionary decompression buffer of a j-th data decompression circuit is shifted to a dictionary decompression buffer of a (j+1)-th data decompression circuit, and
input the dictionary compression results of the third dictionary decompression circuits of the second to N-th data decompression circuits out of the N third dictionary decompression circuits of the N data decompression circuits to the longest match selection circuit.

9. The data compression/decompression system of claim 8, wherein
each of the data compression circuits includes an entropy coding circuit, and
the dictionary buffer concatenation control circuit is configured to
in the first mode,
input dictionary compression results of the N first dictionary compression circuits to the N entropy coding circuits of the N data compression circuits respectively, and
in the second mode,
input the dictionary compression result selected by the longest match selection circuit to the entropy coding circuit of the first data compression circuit, and
set the (N−1) entropy coding circuits of the second to N-th data compression circuits in a non-operated state.

10. A data compression/decompression system, comprising:
a data compression device including a data compression circuit including a first dictionary buffer and a first dictionary compression circuit; and
a data decompression device including a data decompression circuit including a second dictionary buffer and a second dictionary compression circuit, the second dictionary buffer being configured to buffer uncompressed data obtained by decompressing compressed data to be decompressed as dictionary data a buffer, the second dictionary compression circuit being capable of executing dictionary compression using the second dictionary buffer, wherein
the data compression circuit includes
a dictionary buffer concatenation control circuit configured to control switching of a first mode and a second mode, the first mode being a mode in which the data compression circuit operates independently of the data decompression circuit and in which the first dictionary compression circuit executes dictionary compression on the uncompressed data to be compressed, the second mode being a mode in which the data compression circuit and the data decompression circuit cooperate and in which the first dictionary compression circuit and the second dictionary compression circuit execute dictionary compression on the uncompressed data, and
a longest match selection circuit configured to, in the second mode, select a dictionary compression result in which a match length is the longest, from among a match length obtained by dictionary compression of the first dictionary compression circuit and a match length obtained by dictionary compression of the second dictionary compression circuit, and
the dictionary buffer concatenation control circuit is configured to, in the second mode, concatenate the first dictionary buffer and the second dictionary decompression buffer such that oldest dictionary data in the first dictionary buffer of the data compression circuit is shifted to the second dictionary decompression buffer of the data decompression circuit.

11. The data compression/decompression system of claim 10, wherein
the data compression circuit includes an entropy coding circuit, and
the dictionary buffer concatenation control circuit is configured to
in the first mode, input a dictionary compression result of the first dictionary compression circuit to the entropy coding circuit, and
in the second mode, input the dictionary compression result selected by the longest match selection circuit to the entropy coding circuit.

12. The data compression/decompression system of claim 8, wherein
the second dictionary compression circuit is configured to execute hash-based dictionary compression on the uncompressed data.

13. The data compression/decompression system of claim 10, wherein
in the first mode,
the first data compression circuit is configured to execute dictionary compression on data input to the data compression device, and
the data compression device is configured to execute entropy coding on data on which dictionary compression is executed by the first data compression circuit.

14. The data compression/decompression system of claim 10, wherein
the dictionary buffer concatenation control circuit is configured to, in the first mode, cut off the input of the uncompressed data to be compressed to the second dictionary compression circuit of the data decompression device.

15. The data compression/decompression system of claim 10, wherein
the second dictionary compression circuit is configured to execute hash-based dictionary compression on the uncompressed data.

16. A memory system comprising:
a nonvolatile memory; and
a memory controller configured to control the nonvolatile memory, wherein
the memory controller includes a data compression device,
the data compression device includes
N data compression circuits each including a first dictionary compression circuit and an entropy coding circuit, the N being an integer of two or more,
a dictionary buffer concatenation control circuit configured to control switching between a first mode and a second mode, the first mode being a mode in which each of the N data compression circuits operates independently, the second mode being a mode in which the N data compression circuits cooperate, and
a longest match selection circuit configured to select, in the second mode, a dictionary compression result with a longest match length from among dictionary compression results of the N first dictionary compression circuits in the N data compression circuits,
the first dictionary compression circuit includes a dictionary buffer for buffering the uncompressed data to be input and compressed, as dictionary data,
the dictionary buffer concatenation control circuit is configured to
in the first mode,
input the N uncompressed data different from each other to the N dictionary compression circuit of the N data compression circuits, and
input dictionary compression results of the N first dictionary compression circuits to the N entropy coding circuits of the N data compression circuit respectively, and
in the second mode,
concatenate the N dictionary buffers by storing, when registering the dictionary data to an i-th dictionary buffer out of the N dictionary buffers of the N data compression circuits, oldest dictionary data stored in the i-th dictionary buffer in a (i+1)-th dictionary buffer, the i being an integer of 1 or more and N−1 or less,
input same uncompressed data to the N data compression circuits, and
input the dictionary compression result selected by the longest match selection circuit to the entropy coding circuit of the first data compression circuit out of the N entropy coding circuit, and
set the (N−1) entropy coding circuits of the second to N-th data compression circuits in a non-operated state,
the entropy coding circuit of the first data compression circuit out of the N entropy coding circuits is configured to execute entropy coding on the input dictionary compression results, and
the memory controller is configured to write data based on the data on which the entropy coding is executed to the nonvolatile memory.

17. The memory system of claim 16, wherein
the dictionary buffer concatenation control circuit is configured to set the (N−1) entropy coding circuits of the second to N-th data compression circuits in a non-operated state, by interrupting the input of the dictionary compression result.

18. The memory system of claim 17, wherein
the entropy coding circuit includes a delay buffer for buffering a symbol of the dictionary compression result of the first dictionary compression circuit,
each of the second to N-th data compression circuits includes a second dictionary compression circuit for executing dictionary compression using the delay buffer of the entropy coding circuit, and
the dictionary buffer concatenation control circuit is configured to, in the second mode,
further concatenate the dictionary buffer and the delay buffer such that
oldest dictionary data in the dictionary buffer of the N-th data compression circuit is shifted to the delay buffer of the second data compression circuit out of the N delay buffers of the N data compression circuits, and that
oldest dictionary data in a delay buffer of a j-th data compression circuit (where j is an integer of 2 or more and N−1 or less) is shifted to a delay buffer of a (j+1)-th data compression circuit, and
input the dictionary compression results of the second dictionary compression circuits of the second to N-th data compression circuits to the longest match selection circuit.

19. The memory system of claim 16, wherein
the memory controller further includes a data decompression device including N data decompression circuits, for decompressing data read form the nonvolatile memory, which is compressed by the data compression device,
the data decompression circuit includes
a dictionary decompression buffer for buffering uncompressed data obtained by decompressing compressed data to be decompressed, as dictionary data, and
a third dictionary compression circuit configured to execute dictionary compression using the dictionary decompression buffer, and
the dictionary buffer concatenation control circuit is configured to, in the second mode,
further concatenate the dictionary buffer and the dictionary decompression buffer such that
oldest dictionary data in the dictionary buffer of the N-th data compression circuit is shifted to the dictionary decompression buffer of the second data decompression circuit out of the N dictionary decompression buffers of the N data decompression circuits, and that
oldest dictionary data in a dictionary decompression buffer of a j-th data decompression circuit is shifted to a dictionary decompression buffer of a (j+1)-th data decompression circuit, and
input the dictionary compression results of the third dictionary decompression circuits of the second to N-th data decompression circuits out of the N third dictionary decompression circuits of the N data decompression circuits to the longest match selection circuit.

20. The memory system of claim 18, wherein
each of the data compression circuits includes an entropy coding circuit, and
the dictionary buffer concatenation control circuit is configured to
in the first mode,
input dictionary compression results of the N first dictionary compression circuits to the N entropy coding circuits respectively, and
in the second mode,
input the dictionary compression result selected by the longest match selection circuit to the entropy coding circuit of the first data compression circuit, and
set the (N−1) entropy coding circuits of the second to N-th data compression circuits in a non-operated state.
